(19) United States
(12) Patent Application Publication
(10) Pub. No.: US 2013/0058039 A1
(43) Pub. Date: Mar. 7, 2013

(54) PORTABLE TERMINAL WITH A COOLING STRUCTURE

(71) Applicant: Hak Lim LEE, Seoul (KR)

(72) Inventor: Hak Lim LEE, Seoul (KR)

(73) Assignee: PANTECH CO., LTD., Seoul (KR)

(21) Appl. No.: 13/563,688

(22) Filed: Jul. 31, 2012

(30) Foreign Application Priority Data
Sep. 7, 2011 (KR) 10-2011-0090856

(51) Int. Cl. H05K 7/20

(52) U.S. Cl. 361/690

(57) ABSTRACT

A portable terminal includes a cooling structure configured to allow air flow into the portable terminal. A display support frame encompasses an opening and is arranged between the display and the main board including heat generating components of the portable terminal. The display support frame support's the display and a window of the portable terminal and has at least one air injection opening. The portable terminal may include a heat dissipating plate encompassing at least one hole therethrough and arranged on at least a portion of the opening of the display support frame. The portable terminal may include a structural body to dissipate heat and to be connected to a battery of the portable terminal.

### CROSS-REFERENCE TO RELATED APPLICATION

This application claims priority from and the benefit of Korean Patent Application No. 10-2011-0090856, filed on Sep. 7, 2011, which is incorporated by reference for all purposes as if fully set forth herein.

### BACKGROUND

1. Field

Exemplary embodiments of the present disclosure relate to a portable terminal with a cooling structure, and more particularly, to a portable terminal in which an opening in a portion of a frame configured to form an air gap between a display and a heat-generation component.

2. Discussion Of The Background

With the development of semiconductor fabrication technology, components, such as a central processing unit (CPU), used in a portable terminal have been highly integrated and reduced in size. In addition, to meet the demands of users, the portable terminal has been updated to include various multimedia capabilities such as video reproduction, video call, and Internet access. Moreover, with the introduction of the fourth generation wireless standard (“4G”), a load on a CPU has increased, in part, due to the use of dual antennas, and an amount of heat radiated has also increased.

The increased temperature of the portable terminal may contribute to various problems including, defects of components, a reduction in life span, mechanical damages due to thermal expansion, burns (low-temperature burn and high-temperature burn), or displeasure of users.

FIG. 1 is an exploded perspective view illustrating an electronic device according to the conventional art.

Referring to FIG. 1, a thermal conductive filling material 28 may be configured to cool a printed circuit board 24 and a hard disk drive 25 in a case 21a. However, the use of the thermal conductive filling material 28 may result in an increase in thickness of the electronic device. There is an increasing demand for a reduction in the thickness of the portable terminal.

Further, a micro-cooling unit or a heat dissipating fan in conjunction with a heat dissipating plate, or independently thereof, may be used to cool electronic devices. However, in these cooling methods, an additional cooling mechanism or heat dissipation mechanism is installed in an internal space of a portable terminal, which may increase manufacturing costs and the thickness of the electronic device.

### SUMMARY

Exemplary embodiments of the present invention provide an electronic device with a cooling structure, and in particular, a cooling structure configured to allow for air circulation to heat generating regions of an electronic device.

Additional features of the invention will be set forth in the description which follows, and in part will be apparent from the description, or may be learned by practice of the invention.

An exemplary embodiment of the present invention discloses a portable terminal, including: a main board including a heat-generating component; a display to display an image; and a display support frame to support the display and arranged between the main board and the display, the display support frame encompassing an air injection opening, wherein the display is a heat sink to dissipate heat of the heat-generating component.

An exemplary embodiment of the present invention also discloses a cooling structure of an electronic device, including: an external frame encompassing an opening and an air injection opening; a window support jaw arranged on the external frame; and a display supporting jaw arranged on the external frame.

An exemplary embodiment of the present invention also discloses a portable terminal, including: a display to display an image; a window connected to a first side of the display; a display support frame connected to a second side of the display, the display support frame including an external frame encompassing a central opening and an air injection opening, a window support jaw to connect to the window, a display support jaw to connect to the display, a joining support base arranged over the central opening, and a heat dissipating plate encompassing a hole therethrough and arranged on at least a portion of the central opening, the heat dissipating plate including a concavo-convex structure; a main board including a heat generating component; a battery connected to the main board; and an outside case connected to the main board and battery, wherein the display support frame is arranged between the main board and the display, the display is a heat sink for the main board and air enters the portable terminal through the air injection opening and travels to the central opening of the display support frame.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is an exploded perspective view illustrating an electronic device according to the conventional art.

FIG. 2 is a plan view of a portable terminal according to an exemplary embodiment of the present invention.

FIG. 3 is an exploded perspective view of the portable terminal of FIG. 2.

FIG. 4 is a perspective view of a main board of FIG. 3.

FIG. 5 is a perspective view of a display support frame of FIG. 3.

FIG. 6 is a cross-sectional view of the portable terminal of FIG. 2 taken along the line A-A.

FIG. 7 is a cross-sectional view of the portable terminal of FIG. 2 taken along the line B-B.

FIG. 8 is a cross-sectional view illustrating a portable terminal according to an exemplary embodiment of the present invention.

FIG. 9 is a perspective view illustrating a heat dissipation plate of FIG. 8.

FIG. 10 is a cross-sectional view of the portable terminal of FIG. 2 taken along the line C-C.

FIG. 11A is a plan view of a structural body of FIG. 10.

FIG. 11B is a perspective view of a structural body of FIG. 10.

### DETAILED DESCRIPTION OF THE ILLUSTRATED EMBODIMENTS

Exemplary embodiments now will be described more fully hereinafter with reference to the accompanying drawings, in which exemplary embodiments are shown. The exemplary embodiments may, however, be embodied in many different forms and should not be construed as limited to the exemplary embodiments set forth therein. Rather, these embodiments are provided so that the present disclosure will be thorough and complete, and will fully convey the scope of the present disclosure to those skilled in the art. In the description, details of well-known features and techniques may be omitted to avoid unnecessarily obscuring the presented embodiments.

The terminology used herein is for the purpose of describing particular embodiments only and is not intended to be limiting of the present disclosure. As used herein, the singular forms “a,” “an,” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first,” “second,” and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals denote like elements. In the drawings, the size and relative sizes of layers and regions may be exaggerated for clarity.

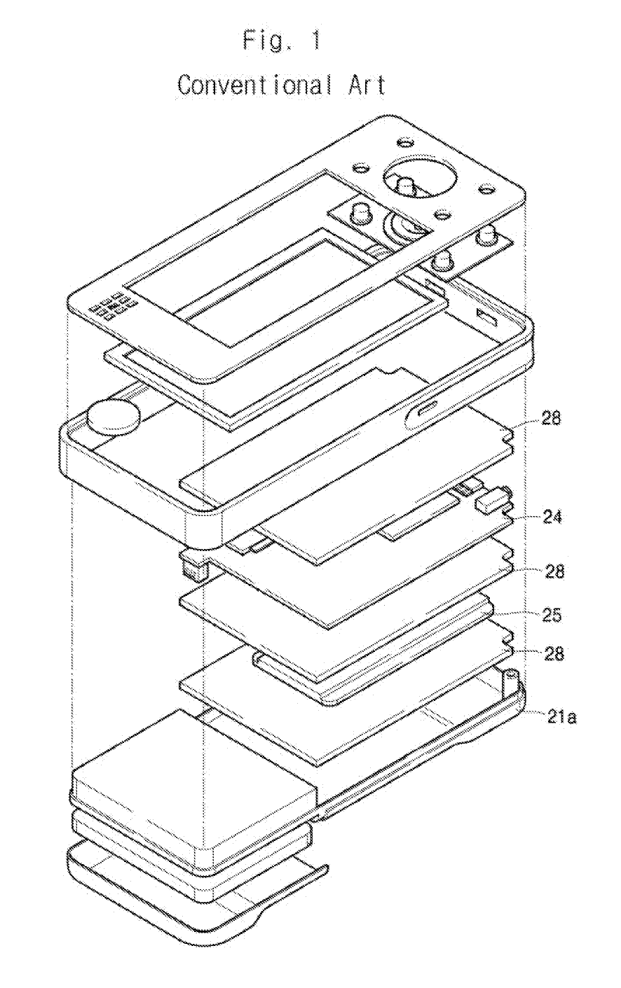

The exemplary embodiments are described with reference to a bar-type portable terminal as illustrated in FIG. 1. However, the present disclosure is not limited thereto, and the exemplary embodiments may also be applied to portable wireless terminals such as folder-type terminals, slide-type terminals, and other terminals of various configurations. Furthermore, the present disclosure may be used to reduce the temperature of components of a portable terminal having high power consumption per volume. Although described with reference to a portable terminal, the present disclosure is not limited thereto and the cooling structure may be applied to various electronic devices with heat-generating components such as portable game machines, cameras, camcorders, etc.

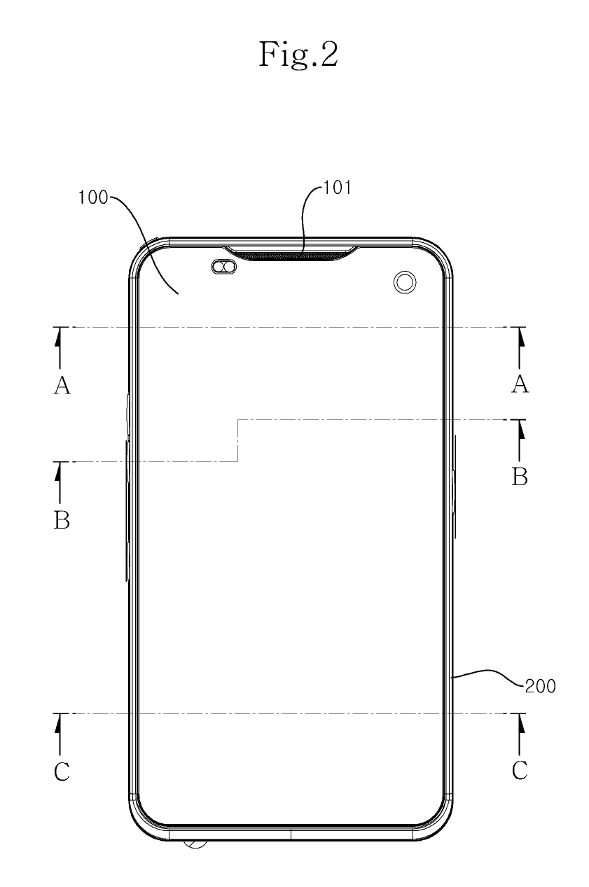

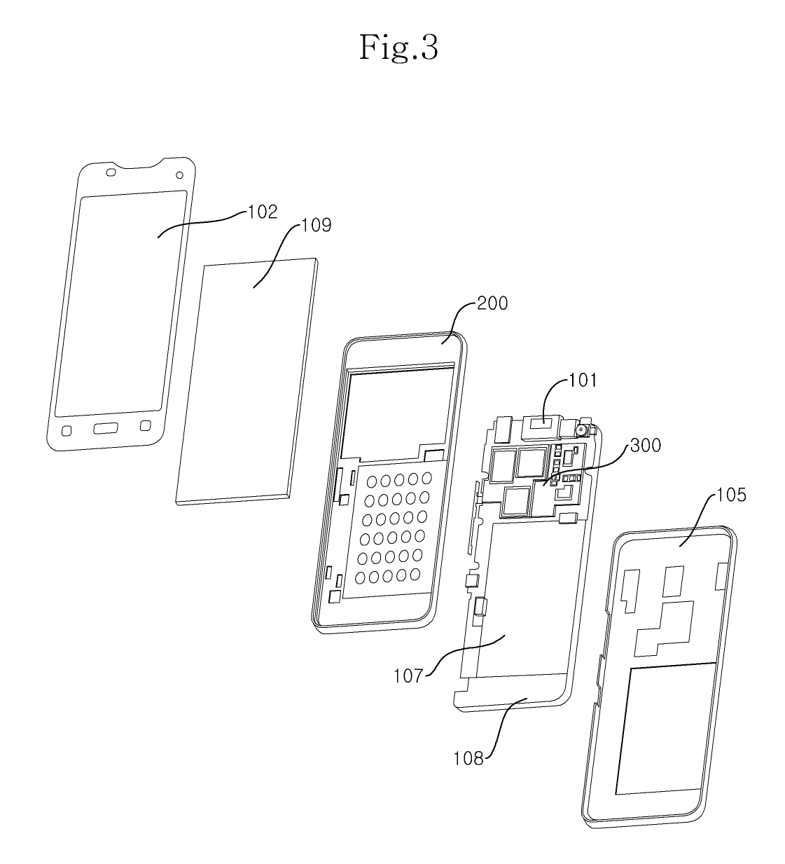

FIG. 2 is a plan view of a portable terminal according to an exemplary embodiment of the present invention. FIG. 3 is an exploded perspective view of the portable terminal of FIG. 2.

Referring to FIG. 2 and FIG. 3, a portable terminal 100 includes, a speaker 101 configured to output an audio signal, a window 102 configured to , a display 109 arranged under the window 102 and configured to display an image, for example by outputting a video signal, a battery 107 configured to supply power, an antenna 108 configured to receive signals, a main board 300 configured to receive various components, for example a main CPU configured to calculate and process various signals, an outside case 105 configured to protect a main board 300, and the like, which may be included in a typical portable terminal. The window 102 may be, for example, an input window such as a screen of a touch screen, and the display 109 may be, for example, a liquid crystal display (LCD).

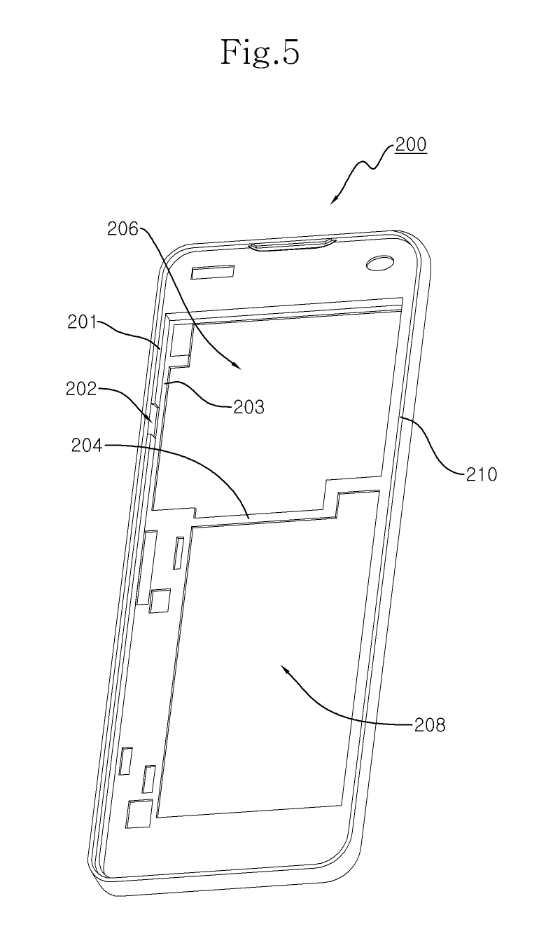

A display support frame 200 is configured to support the display 109 and may be configured such that a portion is opened to form an air gap between the main board 300 configured to receive heat-generation components and the display 109 arranged thereon. The open portion of the display support frame 200 may be in the center of the display support frame 200. The display support frame 200 of the present disclosure will be described with reference to FIG. 5.

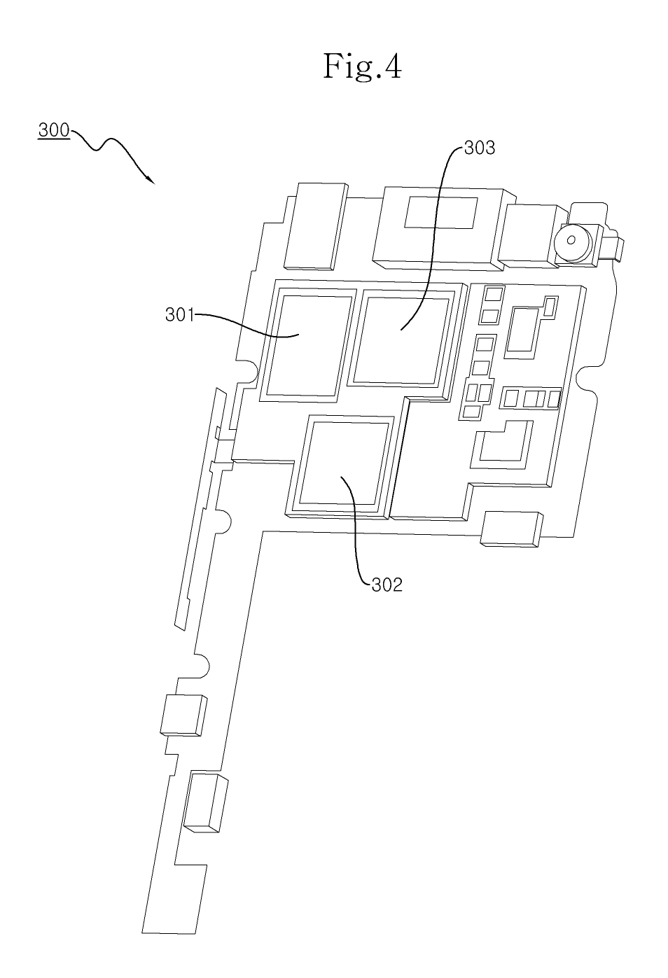

FIG. 4 is a perspective view of the main board of FIG. 3.

Referring to FIG. 4, the main board 300 of the portable terminal 100 includes a memory 301, an application driving chip 302, and a CPU 303. The CPU 303 may include a module chip configured to provide communication. Heat-generating components, such as the application driving chip 302 and the CPU 303, may consume higher amounts of power per volume as a CPU clock speed increases and may generate heat. The generated heat may be transferred to other components and may increase the temperature of not only the component itself but also other components arranged near the component, and may thereby have an adverse effect on the other components.

The generated heat may contribute to defects in the other components, increase a failure rate of electronic components, and reduce the life span of the electronic components. In addition, the generated heat may contribute to mechanical damage, malfunction, and may burn or provide discomfort to a user due to thermal stress and thermal expansion.

The present disclosure introduces a display support frame in FIG. 5 and a method for rapidly dissipating heat generated by the heat-generating components.

FIG. 5 is a perspective view of the display support frame of FIG. 3. Although the display support frame will be described with reference to the portable terminal 100 of FIG. 3, it is not limited as such.

Referring to FIG. 5, an external frame of the display support frame 200 defines an opening in the center portion of the display support frame 200, and at least one or more air injection openings 202 are formed at a side face thereof. Outside air may flow into the portable terminal 100 through the air injection opening 202 and may cool the portable terminal 100. Further the heat inside of the portable terminal 100 may be dissipated through the air injection opening(s) 202.

The display support frame 200 includes a window support jaw 201 configured to support the window 102, and a display support jaw 203 configured to support the display 109 arranged below the window support jaw 201.

The open portion of the display support frame 200 may be partitioned into a first open portion 206 and a second open portion 208 by a joining support base 204. The joining support base 204 may be integrated with the display support frame 200 and configured to reinforce the mechanical strength of the display support frame 200. However, the joining support base 204 may also be provided separately from the display support frame 200.

The main board 300 may be arranged on the lower side of the first open portion 206, and the battery 107 may be arranged on the lower side of the second open portion 208. The display 109 may be arranged on the upper side of the first open portion 206 and second open portion 208.

A strength reinforcement member 210 configured to reinforce the mechanical strength of the display support frame 200 may be connected to the border of the display support frame 200.

Generally, an open portion of a support frame may result in reduction in the strength of the support frame.

The display support frame 200 may be produced of a metal alloy containing magnesium or aluminum. The strength reinforcement member 210 may be produced by an injection molded plastic or the like and may be arranged on the border of the display support frame 200.

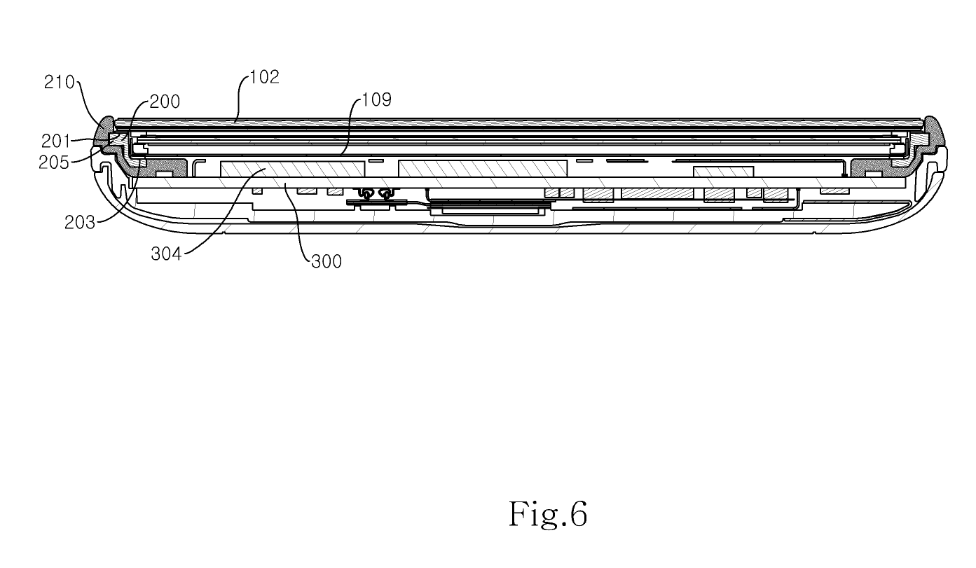

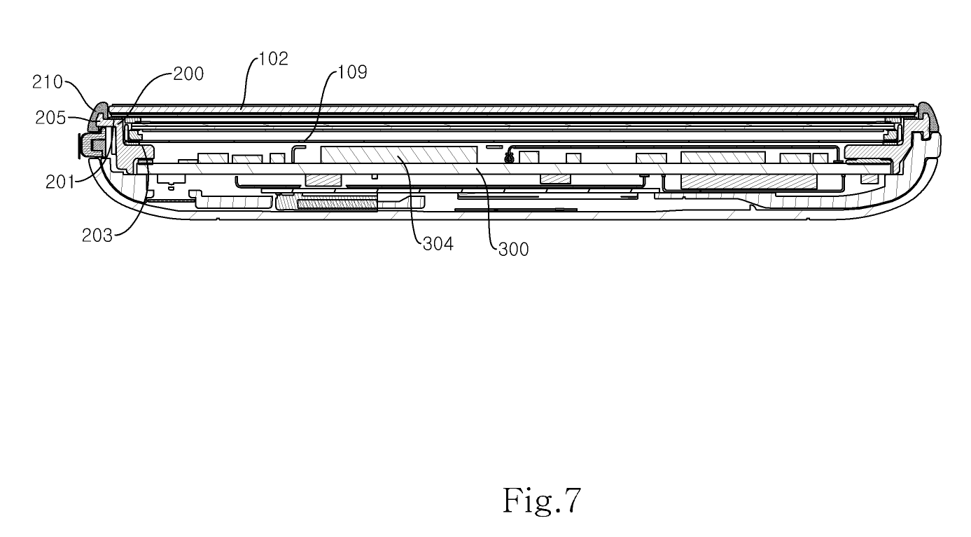

FIG. 6 is a cross-sectional view of the portable terminal of FIG. 2 taken along the line A-A. FIG. 7 is a cross-sectional view of the portable terminal of FIG. 2 taken along the line B-B.

Although a cooling method will be described with reference to the portable terminal 100 of FIG. 2, the cooling method is not limited as such. The window 102 may be arranged on the window support jaw 201 of the display support frame 200, and the display 109 may be arranged on the display support jaw 203 arranged therebelow.

The display 109 and a heat-generation component 304 arranged on the main board 300 may oppose each other in the display support frame 200 and may be separated by a reference distance to form an air gap. The heat-generation component 304 may be any component arranged on the main board 300 that is configured to generate heat. In an example, the heat-generation component 304 may include, without limitation, a memory 301, an application driving chip 302, and a CPU 303 as shown in FIG. 4.

If the display 109 has a larger surface area than the heat-generation component 304 arranged on the main board 300, the display 109 may act as a heat sink for the heat-generation component 304, and heat generated by the heat-generation component 304 may be rapidly transferred to the display 109 through the air gap, thereby dissipating heat.

Outside air may flow into the display frame 200 through the air injection openings 202, depicted with reference to FIG. 5, arranged on the side face of the display support frame 200. The outside air may flow into the air gap between the display 109 and the heat-generation component 304 and may circulate therein to cool the display frame 200. Further, heated air produced in the portable terminal 100 may be dissipated through one or more air injection openings 202 as well.

The display support frame 200 may include a joining portion 205 configured to extend and protrude outward from the window support jaw 201. The strength reinforcement member 210 may be connected to the joining portion 205 and configured to extend outside of the display support frame 200. The strength reinforcement member 210 may reinforce the mechanical strength of the display frame 200. The strength reinforcement member 210 may be formed to accommodate a portion of the joining portion 205 of the display support frame 200. For example, but not limited thereto, the cross-section of a part of the strength reinforcement member 210 connected to the joining portion 205 of the display support frame 200 may have a shape similar to a C shape. Accordingly, if force is exerted on the strength reinforcement member 210 in the vertical direction or the horizontal direction, the strength reinforcement member 210 may not easily be separated from the display support frame 200. This may allow for a stable connection between the display support frame 200 and the strength reinforcement member 210.

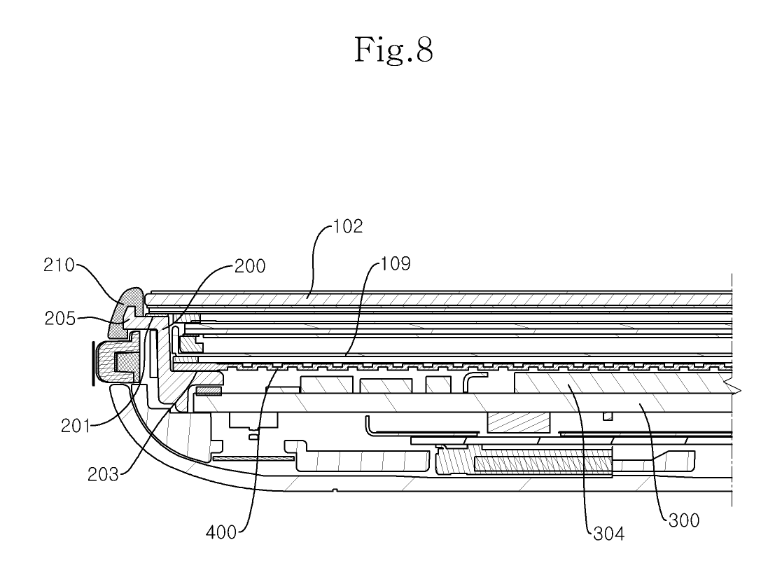

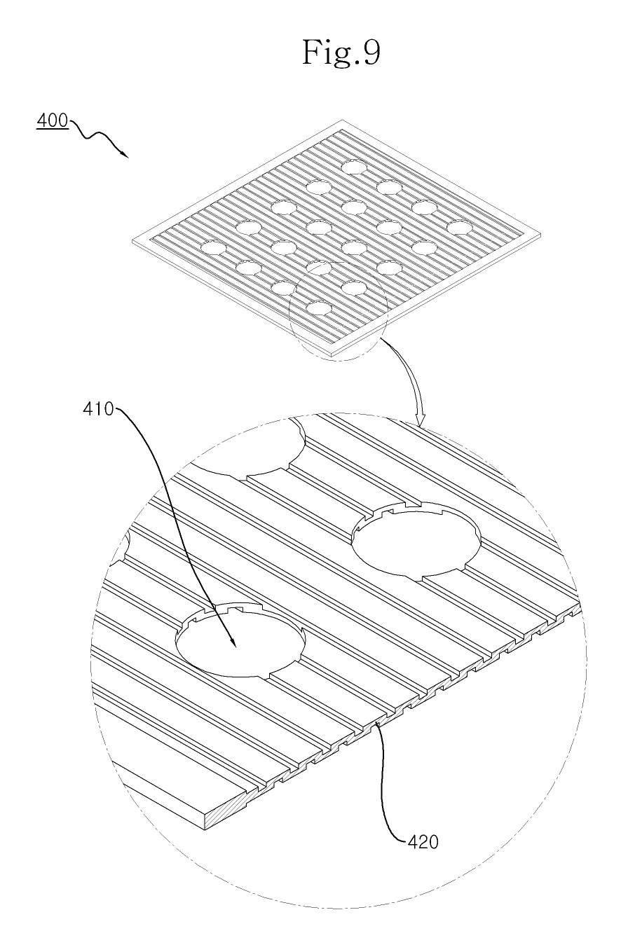

FIG. 8 is a cross-sectional view illustrating a portable terminal according to an exemplary embodiment of the present invention. FIG. 9 is a perspective view illustrating a heat dissipation plate of FIG. 8.

The components of the portable terminal of FIG. 8 except for a heat dissipation plate 400 may be the same as or similar to those of the portable terminal of FIG. 7, and the description of the same or similar components is omitted.

Referring to FIG. 8 and FIG. 9, the heat dissipation plate 400 is arranged in a region between the display 109 and the heat-generation component 304. The surface of the heat dissipation plate 400 may be a concavo-convex structure 420. Concavo-convex structure may refer to a structure that has a cross-section with both a concave shaped and a convex shaped portion. The concavo-convex structure 420 may suppress a temperature increase in the heat-generation component 304 and may extend a heat dissipation area. If the surface of the heat dissipation plate 400 is a concavo-convex structure 420, the heat dissipation area of the display support frame 200 may be extended. The concavo-convex structure 420 may allow for air flow to vary as the air encounters various parts of the concavo-convex structure 420, and this may improve heat dissipation in the display support frame 200.

The heat dissipation plate 400 may include one or more openings 410 through the surface thereof. If openings 410 are present in the heat dissipating plate 400, air flow speed and air flow turbulence may increase. An increase in air flow speed and air flow turbulence in the display frame 200 may improve air circulation for heat dissipation.

A material that may aid in dissipation of heat, such as heat dissipation lubricating oil or heat dissipation gel, may be applied to the surface of the heat dissipation plate 400. The material may increase the heat dissipation rate or amount by the heat dissipation plate 400. The material of the heat dissipation plate 400 may be, for example, a low-melting-point alloy.

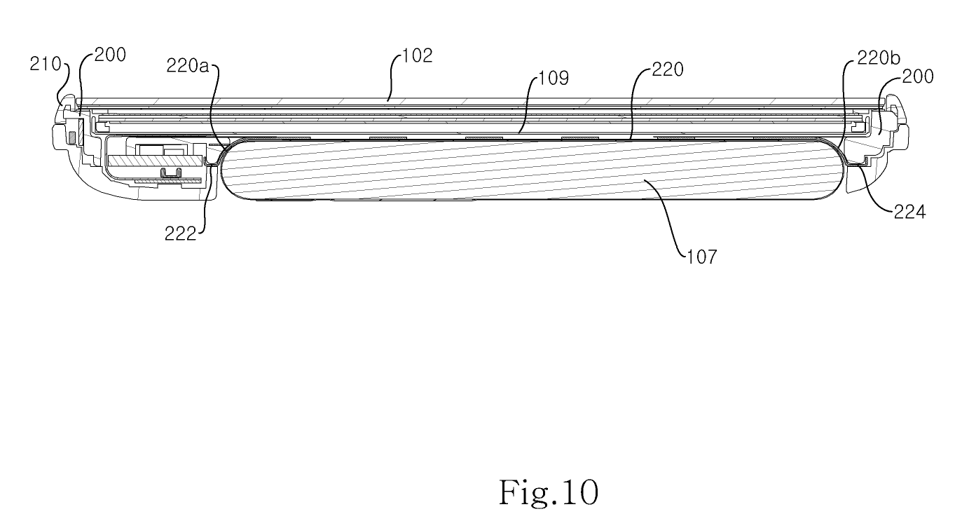

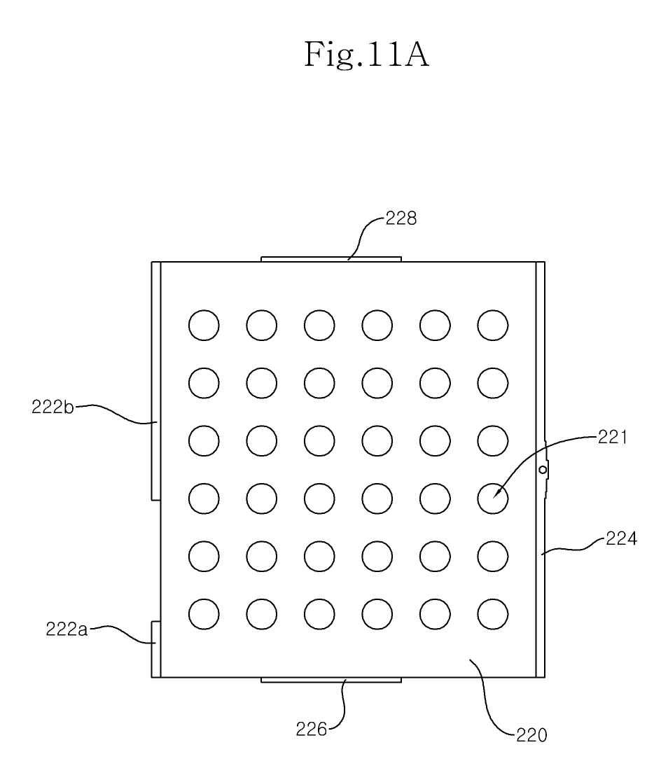

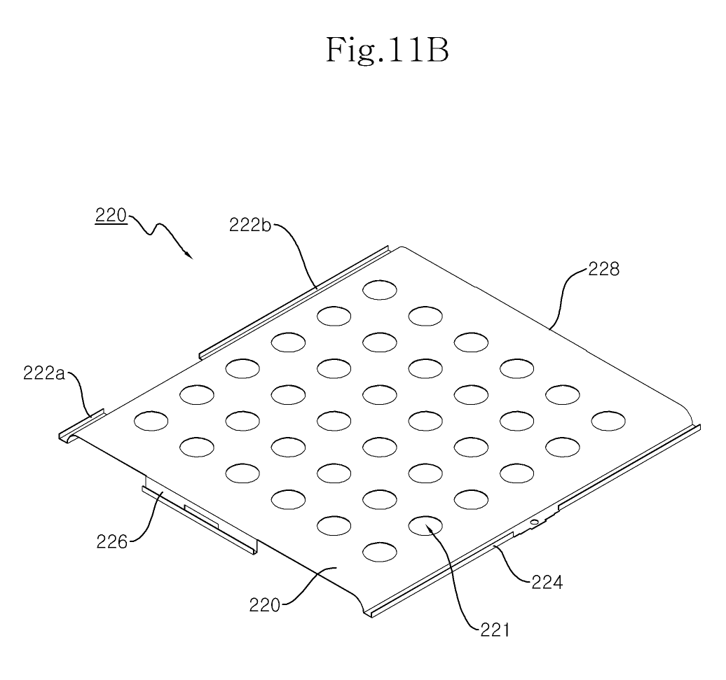

FIG. 10 is a cross-sectional view of the portable terminal of FIG. 2 taken along the line C-C. FIG. 11A is a plan view of a structural body of FIG. 10. FIG. 11B is a perspective view of a structural body of FIG. 10.

Referring to FIG. 10, FIG. 11A, and FIG. 11B, the structural body 220 may be connected to the second open portion 208 of the display support frame 200 of FIG. 5, and the battery 107 may be arranged therebelow. The structural body 220 may include a plurality of through-holes 221. The through-holes 221 may result in a reduction in manufacturing costs and may enhance the heat dissipation of the structural body 220. The structural body 220 may be a stainless steel alloy.

The display 109 may be arranged above the structural body 220. The display 109 may have a surface area through which heat may be dissipated. Heat generated by the battery 107 may be transferred to the display 109 through the structural body 220 to dissipate the generated heat. The thickness of the structural body 220 may be up to about 0.15 mm. The use of a structural body 220 may reduce or eliminate the use of thermal conductive filling material, which may result in a reduction in the thickness of a portable terminal compared to conventional portable terminals.

The structural body 220 may include curved surface 220a and curved surface 220b, each with a reference curvature corresponding to the curved surfaces of both ends of the battery 107.

The structural body 220 may include one or more hook structural objects: hook structural object 222a, hook structural object 222b, hook structural object 224, hook structural object 226, and hook structural object 228 arranged on an outer edge of the structural body 220. The hook structural objects 222a, the hook structural object 222b, the hook structural object 224, the hook structural object 226, and the hook structural object 228 may be connected to the display support frame 220. The hook structural objects 222a, the hook structural object 222b, the hook structural object 224, the hook structural object 226, and the hook structural object 228 may reduce the likelihood of movement of the battery 107.

For example, but not limited thereto, the hook structural object 222a, the hook structural object 222b, the hook structural object 224, the hook structural object 226, and the hook structural object 228 may be configured to have a substantially U-shaped cross-section, and the lower portion of the U-shaped cross-section may be substantially flat and may have sufficient surface area to reduce the likelihood of deflection of the hook structural objects 222a, hook structural object 222b, hook structural object 224, hook structural object 226, and hook structural object 228 due to a force in the vertical direction on the battery 107.

According to exemplary embodiments described above, the use of a cooling structure in a portable terminal may reduce the thickness of the portable terminal by reducing or eliminating the use of a thermal conductive film material and various other structures to aid in heat dissipation, an internal space in a portable terminal occupied by cooling structures may be reduced, and manufacturing costs of the portable terminal may be reduced.

In addition, exemplary embodiments of the portable terminal may dissipate heat generated by the portable terminal. Heat dissipation may aid to reduce product defects that may be related to the generated heat, for example, a short circuit of components, deterioration of the components, and the like.

Furthermore, according to exemplary embodiments the portable terminal may increase a heat dissipation area of a portable terminal when compared to the conventional art, improve cooling operation, and may protect the display from heat related damage.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A portable terminal, comprising:
a main board comprising a heat-generating component;
a display to display an image; and
a display support frame to support the display and arranged between the main board and the display, the display support frame encompassing an air injection opening and a first opening.

2. The portable terminal of claim 1, wherein the display support frame comprises a display support jaw to support the display.

3. The portable terminal of claim 1, wherein the display support frame further comprises a strength reinforcement member.

4. The portable terminal of claim 1, further comprising:
a heat dissipating plate to dissipate heat encompassing at least one hole therethrough,
wherein the heat dissipating plate is arranged on the display support frame.

5. The portable terminal of claim 4, wherein the heat dissipating plate comprises a concavo-convex structure.

6. The portable terminal of claim 4, wherein the display support frame encompasses a second opening and the heat dissipating plate is arranged on the second opening.

7. The portable terminal of claim 1, further comprising:
a structural body to dissipate heat,
wherein the structural body is connected to a battery and the structural body is arranged between the display and the battery.

8. The portable terminal of claim 7, wherein the structural body encompasses a through-hole.

9. The portable terminal of claim 7, wherein the structural body comprises a stainless steel alloy.

10. The portable terminal of claim 1, wherein the display support frame comprises at least one of magnesium and aluminum.

11. The portable terminal of claim 3, wherein the strength reinforcement member comprises a plastic.

12. A cooling structure of an electronic device, comprising:
an external frame encompassing an opening and an air injection opening;
a window support jaw arranged on the external frame; and
a display supporting jaw arranged on the external frame.

13. The cooling structure of claim 12, further comprising:
a joining support base arranged over the opening in the external frame.

14. The cooling structure of claim 12, further comprising:
a heat dissipating plate encompassing at least one hole therethrough,
wherein the heat dissipating plate is arranged on at least a portion of the opening.

15. The cooling structure of claim 14, wherein the heat dissipating plate comprises a concavo-convex structure.

16. The cooling structure of claim 14, further comprising:
a strength reinforcement member.

17. The cooling structure of claim 14, further comprising at least one of a heat dissipating lubricating oil and heat dissipating gel arranged on a surface of the heat dissipating plate.

18. The cooling structure of claim 12, wherein the display support frame comprises at least one of magnesium and aluminum.

19. The cooling structure of claim 16, wherein the strength reinforcement member comprises a plastic.

20. A portable terminal, comprising:
a display to display an image;
a window connected to a first side of the display;
a display support frame connected to a second side of the display, the display support frame comprising an external frame encompassing a central opening and an air injection opening, a window support jaw to connect to the window, a display support jaw to connect to the display, a joining support base arranged over the central opening, and a heat dissipating plate encompassing a hole therethrough and arranged on at least a portion of the central opening, the heat dissipating plate comprising a concavo-convex structure;
a main board comprising a heat generating component;
a battery connected to the main board; and
an outside case connected to the main board and battery,
wherein the display support frame is arranged between the main board and the display, the display is a heat sink for the main board and air enters the portable terminal through the air injection opening and travels to the central opening of the display support frame.
